(19) United States
(12) Patent Application Publication
(10) Pub. No.: US 2021/0351332 A1
(43) Pub. Date: Nov. 11, 2021

(54) OPTOELECTRONIC SEMICONDUCTOR COMPONENT

(71) Applicant: OSRAM Opto Semiconductors GmbH, Regensburg (DE)

(72) Inventors: Michael Völkl, Regensburg (DE); Siegfried Herrmann, Neukirchen (DE)

(21) Appl. No.: 17/284,400

(22) PCT Filed: Oct. 2, 2019
(86) PCT No.: PCT/EP2019/076725

§ 371 Date: Apr. 9, 2021

(30) Foreign Application Priority Data
Oct. 12, 2018 (DE) 10 2018 125 281.1

(51) Int. Cl. H01L 33/62; H01L 33/14; H01L 33/30

(52) U.S. Cl. CPC H01L 33/62; H01L 33/30; H01L 33/14

(57) ABSTRACT

In one embodiment, the optoelectronic semiconductor device has a semiconductor layer sequence arranged to generate red or orange light. A plurality of electrical through-connections extend through the semiconductor layer sequence. A first main side of the semiconductor layer sequence is electrically contacted by a first electrical contact structure. A second electrical contact structure is located on the first main side. The second contact structure electrically connects the through-connections to one another. The second contact structure is embedded in the first contact structure.

### CROSS REFERENCE TO RELATED APPLICATIONS

This patent application is a national stage entry from International Application No. PCT/EP2019/0767255, filed on Oct. 2, 2019, published as International Publication No. WO 2020/074351 A1 on Apr. 16, 2020, and claims priority under 35 U.S.C. §119 from German patent application 10 2018 125 281.1, filed Oct. 12, 2018, the entire contents of all of which are incorporated by reference herein.

### FIELD

An optoelectronic semiconductor device is specified.

### BACKGROUND

A task to be solved is to specify an optoelectronic semiconductor device which emits in the red spectral range and can be operated efficiently at high current densities.

### SUMMARY

This task is solved inter alia by an optoelectronic semiconductor device having the features of claim 1. Preferred further developments are the subject of the dependent claims.

According to at least one embodiment, the semiconductor device comprises a semiconductor layer sequence. The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or an arsenide compound semiconductor material such as AlₙIn₁₋ₙ₋ₘGaₘAs or such as AlₙGaₘIn₁₋ₙ₋ₘAsₖP₁₋ₖ, wherein in each case 0≤n≤1, 0≤m≤1 and n+m>1 as well as 0≤k<1. Preferably, for at least one layer or for all layers of the semiconductor layer sequence, 0<n≤0.8, 0.4≤m<1 and n+m≤0.95 as well as 0<k≤0.5. In this context, the semiconductor layer sequence may comprise dopants as well as additional components. For simplicity, however, only the essential constituents of the crystal lattice of the semiconductor layer sequence, i.e., Al, As, Ga, In, N, or P, are specified, even if these may be partially replaced and/or supplemented by small amounts of additional substances.

According to at least one embodiment, the semiconductor layer sequence is configured to generate orange and/or red and/or yellow light. Preferably, the semiconductor layer sequence is based on the material system AlInGaP for this purpose. The generated light is incoherent radiation, i.e. not laser light. Thus, the semiconductor device is a light emitting diode and not a laser diode.

According to at least one embodiment, the semiconductor layer sequence comprises a first main side and a second main side. The second main side is opposite to the first main side. The main sides are preferably oriented perpendicular to a growth direction of the semiconductor layer sequence. The main sides may be formed by planar surfaces or may comprise structures such as roughenings especially for improving a light out coupling.

According to at least one embodiment, the semiconductor device comprises a plurality of electrical through-connections. The through-connections run predominantly or completely through the semiconductor layer sequence. In particular, this means that the through-connections can penetrate both the first main side and the second main side of the semiconductor layer sequence.

According to at least one embodiment, the semiconductor device comprises a first electrical contact structure. Via the first electrical contact structure, the first main side is electrically contacted in a planar manner. “Planar” means in particular that at least 50% or 70% or 80% or 90% of the first main side, as seen in a plan view of the first main side, are covered by the first electrical contact structure and are supplied with current by the first electrical contact structure.

According to at least one embodiment, the semiconductor device comprises at least one second electrical contact structure. The second contact structure or structures are located on the first main side. However, the second electrical contact structure is electrically separated from the first main side, so that there is no ohmic electrical connection between the second contact structure and the first main side. In contrast, the first contact structure is preferably ohmically conductively connected to the first main side.

According to at least one embodiment, the at least one second contact structure electrically connects several or all of the through-connections to each other. In particular, the through-connections are ohmically conductively connected to each other via the second contact structure. In other words, the through-connections may originate from the at least one second contact structure and partially or fully penetrate the semiconductor layer sequence.

According to at least one embodiment, the second contact structure is partially or fully embedded in the first contact structure. In this case, the first contact structure and the second contact structure are not electrically in direct contact with each other, but are electrically insulated from each other. An electrical connection between the first contact structure and the second contact structure is preferably provided exclusively via the semiconductor layer sequence and optionally via a protective element against damage caused by electrostatic discharges.

The fact that the second contact structure is embedded in the first contact structure means, for example, that side surfaces of the second contact structure are completely or predominantly covered by a material of the first contact structure, as seen in projection onto the side surfaces. End surfaces of the second contact structure may be excluded from this. That is, longitudinal sides of the second contact structure may be completely or predominantly covered by the first contact structure. Furthermore, the second contact structure may be predominantly located between the first contact structure and the semiconductor layer sequence. That is, the second contact structure may be at least partially covered by the first contact structure.

Here and hereinafter, the term “predominantly” means a portion of at least 50% or 70% or 80% or 90%.

In at least one embodiment, the optoelectronic semiconductor device comprises a semiconductor layer sequence configured to generate red or orange light. The semiconductor layer sequence comprises a first main side and a second main side. A plurality of electrical through-connections extend predominantly or completely through the semiconductor layer sequence, but at least through an active zone of the semiconductor layer sequence. The first main side is electrically contacted by a first electrical contact structure. At least one second electrical contact structure is located on the first main side. The at least one second contact structure electrically connects several or all of the through-connections to each other. The second contact structure is partially or fully embedded in the first contact structure.

For example, in headlight applications and in projection applications, high luminance densities are typically required. This is especially true for red light, which is generated directly in a semiconductor layer sequence without additional phosphors. InGaAlP LED chips are frequently used for this purpose. In such LED chips, a p-type side is only partially electrically and thermally connected, so that limitations exist with regard to maximum current density and thermal resistance. This is due in particular to the fact that electrical insulation layers are usually designed over the entire surface and form a thermal barrier.

The semiconductor device described here is in particular an InGaAlP high-current LED chip that can be efficiently deheated and thus comprises a small thermal resistance towards a heat sink. This allows higher current densities and thus luminance levels to be achieved. Due to the through-connections, a selectively adjustable or a particularly more homogeneous energization of the semiconductor layer sequence is possible.

The InGaAlP LED chip described here is in particular a flip chip that is functionally and geometrically modified compared with conventional red-emitting LED chips in order to achieve high current densities with low thermal resistance. Here, either a p-type side or an n-type side can form the first main side where the electrical contact structures are located.

In the semiconductor device described herein, the following features in particular may be fulfilled, individually or in combination:
Both n-contacts and p-contacts are led towards a mounting surface.
In particular, the n-contact is electrically and thermally connected over almost the entire surface.
The p-contacts are connected to the p-side via conductor tracks by means of through-connections. Current spreading can be achieved by means of transparent electrically conductive layers such as ITO layers on the p-side.
Microprisms may be etched which are located on the p-type side and/or on the n-type side. Increased light extraction efficiency can be achieved by means of such microprisms.
Electrical conductor tracks may be completely or partially mirrored, in particular electrical conductor tracks for the second contact structure.
On an n-type main side of the semiconductor layer sequence, metal mirrors and DBR mirrors can be attached alternately and in particular in rows.
Comparatively thick electrical contact structures, for example with a thickness of at least 50 μm or 100 μm, can be applied, in particular galvanically.
A growth substrate and/or a carrier made of sapphire, for example, may be detached to obtain a so-called top emitter.
For current spreading especially on the second main side, not only through-connections may be present, but additional transparent current spreading layers such as ITO layers and/or metal webs.

The microprisms on the first main side and/or on the second main side can be used to adjust a local current supply in the semiconductor layer sequence. This applies in particular if a current spreading layer of the semiconductor layer sequence is etched away locally or over the entire area, so that etched areas are hardly supplied with current. This does not adversely affect the whole-area thermal contact. In addition, microprisms can be used to scatter light for increased outcoupling efficiency or for improved coupling into an optical element on the semiconductor layer sequence, such as a sapphire substrate, for example a patterned sapphire substrate or PSS for short.

Instead of microprisms, in particular on the second main side, patterned sapphire carriers, i.e. PSS carriers, can also be used. The microprisms can be matched to current ridges, in particular to the second contact structure, and/or to the microprisms on the opposite main side of the semiconductor layer sequence. This can prevent light from being generated directly below and/or above the ridges of the second contact structure.

With the semiconductor device described herein, high current densities can be achieved with efficient heat dissipation. The waste heat is preferably dissipated completely via a metallic chip base. This is made possible in particular because only partial line-shaped insulation layers are present on the second contact structure, in contrast to conventional InGaAlP LED chips in which a full-surface insulation layer is applied and this insulation layer is interrupted only in small regions. Due to the conductor tracks of the second contact structure, the semiconductor chip described here can be supplied with current much more homogeneously or different regions of the semiconductor layer sequence can be supplied with current to different degrees.

The semiconductor device described herein can be installed as a flip chip and can be used in a wide variety of packages. Exemplary applications for semiconductor devices described herein are in headlights and projection applications. It is also possible to install it in package designs, for example with a white frame made of a plastic. Combination with various conversion technologies, i.e., phosphors, is possible. The LED chips described here can be mounted in packages based on ceramics or based on leadframes, as well as on printed circuit boards or metal core boards. Combination with reflector arrangements is possible. Current distribution structures, which are located on the second main side and extend from the through-connections and which are, for example, star-shaped, can be electrically contacted via the second contact structure individually or together, in particular via bonding wires.

According to at least one embodiment, a current spreading layer is located on the second main side. The current spreading layer is preferably made of a transparent material such as a transparent conductive oxide, TCO for short. For example, the current spreading layer is made of ZnO or of ITO.

According to at least one embodiment, the through-connections terminate in or on the current spreading layer. In particular, this means that the through-connections overhang the second main side in the direction away from the first main side. Alternatively, the through-connections end before the second main side still within the semiconductor layer sequence.

According to at least one embodiment, the first contact structure comprises a first contact pad for external electrical contacting of the semiconductor device. The first contact pad is preferably configured for solder contacting.

According to at least one embodiment, the at least one second contact structure comprises one or more second contact pads. The at least one second contact pad is also configured for external electrical contacting of the semiconductor device. For example, the first contact pad is an anode contact and the at least one second contact pad is a cathode contact, or vice versa.

According to at least one embodiment, all contact pads are located on the first main side. Thus, the semiconductor device is a flip chip. In this case, all contact pads may be covered by the semiconductor layer sequence. That is, the contact pads preferably do not protrude laterally over the semiconductor layer sequence, viewed in cross-section perpendicular to the main sides.

According to at least one embodiment, the first main side and/or the second contact structure are predominantly, preferably at least 80%, covered by the first contact pad when viewed from above the first main side. That is, a major part of a base surface of the semiconductor device at the mounting side may be occupied by the first contact pad. The first contact pad may be a largest connection surface of the semiconductor device.

According to at least one embodiment, the first contact pad completely covers a central region of the first main side without interruption. The first contact pad may be a continuous, uninterrupted contact pad. Preferably, the central region is located centrally and/or at least in the center on the first main side.

According to at least one embodiment, the first contact pad leaves an edge of the first main side partially or completely free. That is, the first contact pad does not extend, at least in places, to an edge of the first main side, as seen in a plan view of the first main side. In the edge that is free of the first contact pad, the at least one second contact pad is preferably located. Alternatively, it is possible that the second contact pad is arranged within the first contact pad, seen in a plan view of the first main side.

According to at least one embodiment, the second contact structure comprises a plurality of strips, also referred to as conductor tracks or ridges. The strips protrude beyond the first contact pad as viewed in a plan view of the first main side. That is, the strips laterally overhang the first contact pad. The strips may project beyond the first contact pad on one, two, three or even four sides, in particular on two opposite sides.

It is possible for the strips to project beyond the first contact pad into the central region, so that the first contact pad can form a ring around a region in which the strips for the at least one second contact pad are exposed.

According to at least one embodiment, the second contact pad or contact pads are respectively attached to ends of the strips of the second contact structure. Thus, the at least one second contact pad is preferably located at the edge, as seen in a plan view of the first main side. Alternatively, the at least one second contact pad is located in a central region of the first main side.

According to at least one embodiment, a plurality of second electrical contact structures are provided. It is thus achievable that the through-connections can preferably be controlled electrically independently of one another in groups. Exactly one second electrical contact pad can be provided per group of through-connections, or several, in particular exactly two second contact pads.

According to at least one embodiment, the semiconductor device comprises a carrier. The carrier may be that component of the semiconductor device which mechanically carries and supports the semiconductor device. The carrier is preferably made of a dielectric material and is preferably transparent to light, in particular yellow, orange and/or red light. Preferably, the carrier is located on the second main side.

The carrier is attached to the semiconductor layer sequence, for example, by means of bonding, in particular wafer bonding or anodic bonding, adhesive bonding or soldering. The carrier may be located directly on the semiconductor layer sequence. Alternatively, at least or only one further layer, in particular a bonding agent layer such as a solder layer or an adhesive layer, is located between the carrier and the semiconductor layer sequence. Optionally, functional layers such as planarization layers, electrical insulation layers, heat spreaders and/or electrical contact layers are present, in addition to the optionally present bonding agent layer.

According to at least one embodiment, the carrier covers the second main side predominantly or completely. It is possible that the carrier forms a light outcoupling element of the semiconductor device. For this purpose, the carrier may be lens-shaped, for example as a converging lens.

According to at least one embodiment, the semiconductor device comprises one or more current distribution structures. The preferably multiple current distribution structures are in particular metallic structures.

According to at least one embodiment, the current distribution structures extend over a port of the second main side. In this case, the current distribution structures preferably each extend from the through-connections. In the direction away from the through-connections, a conductor cross-section of the current distribution structures may decrease.

According to at least one embodiment, the current distribution structures extend away from each associated through-connections in a star-shaped or a cross-shaped form when viewed in a plan view of the second main side. A one-to-one assignment between the through-connections and the current distribution structures may be given.

According to at least one embodiment, exactly one current distribution structure is present. This current distribution structure may extend over the second main side as a grid when viewed in a plan view of the second main side. All through-connections can be electrically connected to each other via such a current distribution structure.

According to at least one embodiment, the at least one current distribution structure is embedded in the current spreading layer. This means, for example, that the at least one current distribution structure is covered by a material of the current spreading layer on a side facing the semiconductor layer sequence as well as on a side facing away from the semiconductor layer sequence. This applies in particular in regions adjacent to the through-connections.

According to at least one embodiment, the at least one current distribution structure is located on a side of the current spreading layer facing away from the semiconductor layer sequence. That is, the current spreading layer may be overhung by the current distribution structure in a direction away from the semiconductor layer sequence. Likewise, this means that the current spreading layer and the current distribution structure can be flush with each other in the direction away from the semiconductor layer sequence.

According to at least one embodiment, the current distribution structure is located on a side of the current spreading layer facing away from the semiconductor layer sequence and is preferably not embedded therein. In contrast, the current distribution structure may be embedded in an adhesive. By means of the adhesive, the carrier is attached to the current spreading layer. Thus, the current distribution structure may be located between the current spreading layer and the carrier.

According to at least one embodiment, the semiconductor device comprises at least one contact mirror. The contact mirror is located at the second contact structure at least towards the first main side. Preferably, the contact mirror is a DBR mirror comprising a plurality of pairs of layers with layers of high and low refractive index for radiation generated during operation. It is possible that the second contact structure is partially or fully encapsulated or embedded in the contact mirror, such that side surfaces of the contact structure and/or a side of the second contact structure facing away from the semiconductor layer sequence may also be covered by the contact mirror. Preferably, the contact mirror leaves the first main side predominantly exposed, in particular to at least 90%.

According to at least one embodiment, the contact mirror is reflective for yellow, orange and/or red light. This means, for example, that a reflectance of the contact mirror for radiation generated during operation is at least 80% or 90% or 95% or 98%.

According to at least one embodiment, the contact mirror serves as an electrically insulating component. That is, no electrical current flows through the contact mirror during intended use of the semiconductor device. For example, the contact mirror is composed of dielectric layers such as oxide layers and/or nitride layers or comprises at least one dielectric layer.

According to at least one embodiment, the through-connections exhibit a density gradient when viewed in a plan view the second main side. That is, the through-connections may be closer together in certain regions and comprise a greater distance from each other in other regions. The density of the through-connections is averaged over a plurality of the through-connections, for example over at least ten or twenty through-connections.

According to at least one embodiment, the through-connections are arranged more densely in a center of the second main side than at an edge of the second main side. This allows higher current densities to be present in the center of the semiconductor layer sequence when viewed in a plan view, and higher luminance to be generated at the center than at the edge.

According to at least one embodiment, the semiconductor device comprises one or more radiation apertures. The at least one radiation aperture partially covers the second main side, preferably from the edge. That is, a central region of the second main side is preferably free of the radiation aperture. In particular, the radiation aperture leaves free a region in which the through-connections are arranged with a higher areal density.

According to at least one embodiment, the radiation aperture is opaque. Additionally, the radiation aperture may be diffusely reflective. For example, the radiation aperture is made of a plastic such as a silicone to which reflective particles, for example made of a metal oxide such as titanium dioxide, are added.

According to at least one embodiment, the semiconductor layer sequence is n-doped on the first main side and p-doped on the second main side. Likewise, the reverse may apply.

According to at least one embodiment, a transparent and electrically conductive interconnection layer, preferably made of a TCO such as ITO, is located directly between the first main side and the first contact structure. Preferably, the through-connections also extend completely through the interconnection layer.

According to at least one embodiment, the semiconductor device is intended for a current density in the semiconductor layer sequence of at least 10 A/cm² or 30 A/cm². In other words, the semiconductor device is intended to be operable at high current densities.

### BRIEF DESCRIPTION OF THE DRAWINGS

In the following, an optoelectronic semiconductor device described here will be explained in more detail with reference to the drawing using exemplary embodiments. Identical reference signs specify identical elements in the individual figures. However, no references to scale are shown; rather, individual elements may be shown in exaggerated size for better understanding.

In the figures:

FIG. 1 shows a schematic sectional view of an exemplary embodiment of an optoelectronic semiconductor device described herein,

FIG. 2 shows a schematic perspective view of an exemplary embodiment of an optoelectronic semiconductor device described herein,

FIGS. 3 to 9 shows in figure parts A schematic sectional views and in figure parts B schematic plan views of method steps of a manufacturing method for optoelectronic semiconductor devices described herein,

FIGS. 10 to 17 shows in figure parts A schematic sectional views and in figure parts B schematic plan views of method steps of a manufacturing method for optoelectronic semiconductor devices described herein,

FIGS. 18 to 20 shows in figure parts A schematic sectional views and in figure parts B schematic plan views of method steps for manufacturing optoelectronic semiconductor devices described herein,

FIG. 21 shows a schematic sectional view of a method step for manufacturing optoelectronic semiconductor devices described herein,

FIGS. 22A, 22B and 23 to 26 shows schematic plan views of exemplary embodiments of optoelectronic semiconductor devices described herein,

FIG. 27 shows a schematic sectional view of an exemplary embodiment of an optoelectronic semiconductor device described herein, and

FIG. 28 shows a schematic plan view of a first main side for an optoelectronic semiconductor device described herein.

### DETAILED DESCRIPTION

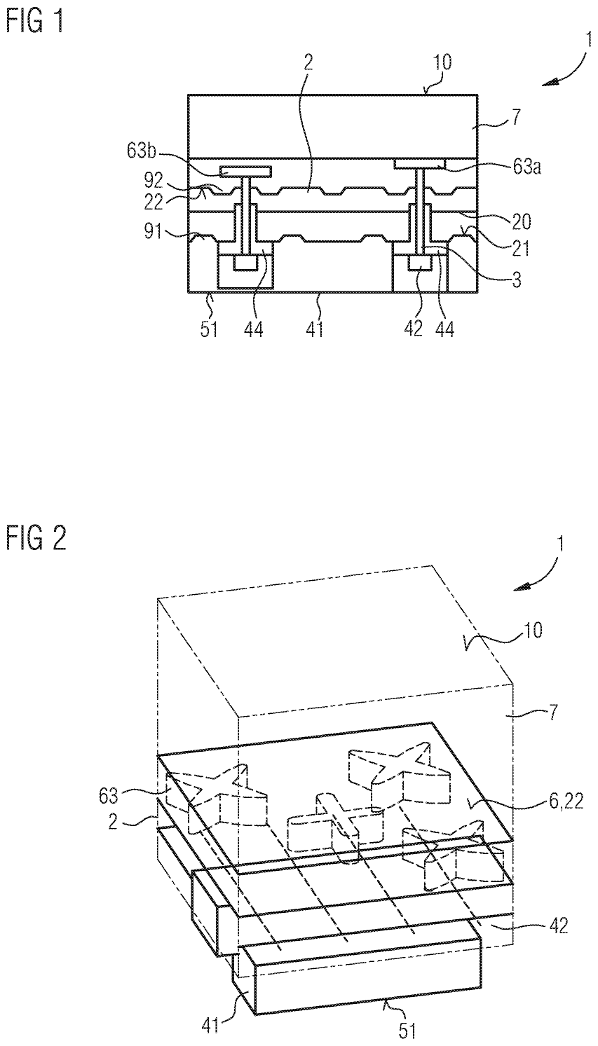

In FIG. 1 an exemplary embodiment of an optoelectronic semiconductor device 1 is shown. The semiconductor device 1 comprises a semiconductor layer sequence 2 having an active zone 20 for generating red light. The semiconductor layer sequence comprises a first main side 21 and a second main side 22 opposite thereto. The semiconductor layer sequence 2 is preferably based on AlInGaP.

Optionally, the main sides 21, 22 are provided with a structuring of first microprisms 91 and/or with a structuring of second microprisms 92. The microprisms 91, 92 are preferably arranged alternately on the main sides 21, 22. In particular, second microprisms 92 are each located close to electrical through-connections 3 through the semiconductor layer sequence 2. Due to the microprisms 91, 92, an undrawn current distribution layer of the semiconductor layer sequence 2 can be removed or thinned, so that a current distribution in the semiconductor layer sequence 2 can be adjusted by means of the microprisms 91, 92.

The semiconductor layer sequence 2 and thus the main sides 21, 22 are penetrated by electrical through-connections 3. The through-connections 3 project beyond the semiconductor layer sequence on both main sides 21, 22. The through-connections 3 are, for example, metal-filled holes through the semiconductor layer sequence 2.

A current spreading layer 6 is located on the second main side 22. The current spreading layer 6 is, for example, made of ITO. Current distribution structures 63a, 63b are located in the current spreading layer 6 or on the current spreading layer 6. The current distribution structures may be of different designs. For example, the current distribution structures 63a are located on a side of the current spreading layer 6 facing away from the semiconductor layer sequence 2. In this case, these current distribution structures 63a may be flush with the current spreading layer 6.

In contrast, the current distribution structures 63b lie completely within the current spreading layer 6. The current spreading layer 6 can thus form a planarization for the current distribution structures 63a, 63b. Preferably, within the semiconductor device 1, all current distribution structures 63a, 63b are of identical design.

A carrier 7 is optionally located at the current spreading layer 6. The carrier 7 is in particular made of a material with a high optical refractive index, for example sapphire. Deviating from the representation of FIG. 1, the carrier 7 can be provided with light incoupling structures and/or with light outcoupling structures, comprise anti-reflective coatings and/or be shaped as an optical element like a lens. An emission side 10 of the semiconductor device 1 is formed by the carrier 7 according to FIG. 1.

On the first main side 21 there are a planar first electrical contact structure 41 and line-shaped second electrical contact structures 42. The contact structures 41, 42 are preferably each formed by metals. By means of the second contact structures 42, the through-connections 3 and thus the current distribution structures 63a, 63b and also the current spreading layer 6 are electrically connected.

To avoid electrical short circuits, the second contact structures 42 are preferably embedded in an electrically insulating contact mirror 44. In particular, the contact mirror 44 is formed by a Bragg mirror on a side of the second contact structures 42 facing the semiconductor layer sequence 2.

In a direction away from the semiconductor layer sequence 2, the contact mirror 44 can be overlapped by the first contact structure 41, see FIG. 1, left side, or can be flush with the first contact structure 41, see FIG. 1, right side.

A first electrical contact pad 51 for external electrical contacting of the semiconductor device 1 is formed by an underside of the first contact structure 41. Second contact pads 52, which are located at the second contact structures 42, are not drawn in the sectional view of FIG. 1.

The contact mirror 44 covers only a small part of the first main side 21. There are preferably no electrically insulating layers laterally beside of the contact mirror 44. This allows current to flow between the first contact pad 51 and the first main side 21 in regions adjacent to the contact mirror 44 in a direction perpendicular to the first main side 21. Furthermore, efficient heat dissipation is possible in these regions adjacent to the contact mirror 44. As a result, the semiconductor device 1 can be operated with high current densities.

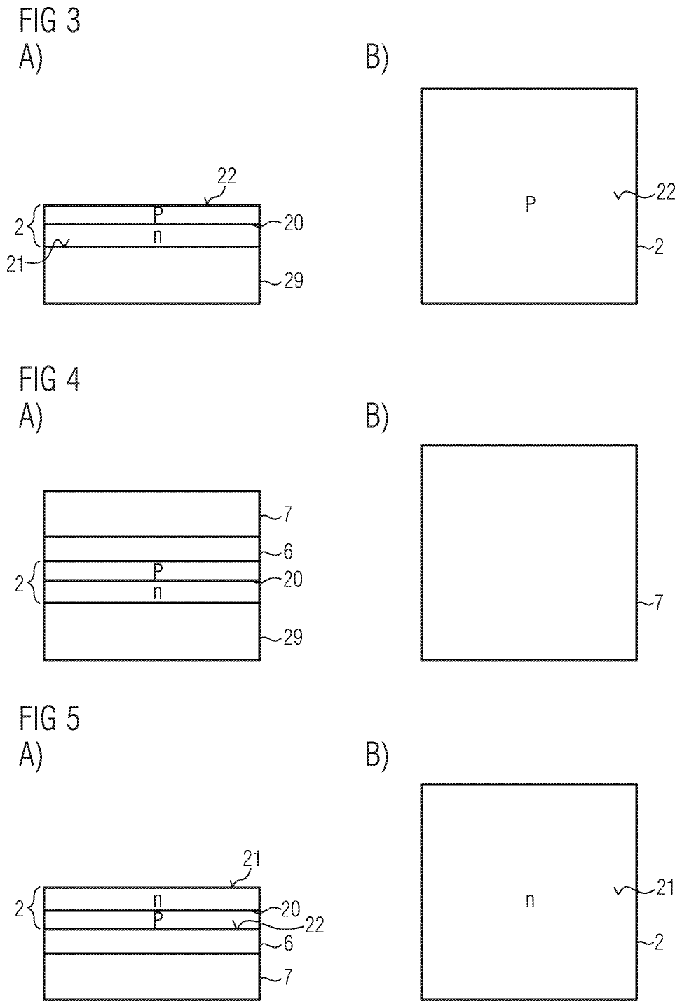

In the exemplary embodiment of FIG. 2, it can be seen that the current distribution structures 63 can be realized by star-shaped structures extending from the through-connections on the second main side 22. Thereby, all current distribution structures 63 may comprise the same geometry. Alternatively to the representation of FIG. 2, the current distribution structures 63 may comprise different geometries. For example, adjacent current distribution structures 63 may be arranged twisted relative to each other to achieve a more uniform current distribution across the semiconductor layer sequence 2.

A degree of coverage of the second main side 22 with the current distribution structures 63 is preferably low. For example, this degree of coverage is at most 20% or 10% or 5%. The current distribution structures 63 are in particular made of a metal and are preferably comparatively thick, for example at least 0.5 μm or at least 1 μmm thick and/or at most 6 μm or at most 4 μm thick, in order to comprise a low electrical resistance. Thus, the current distribution structures 63 are opaque.

In all other respects, the statements on FIG. 1 apply mutatis mutandis to FIG. 2.

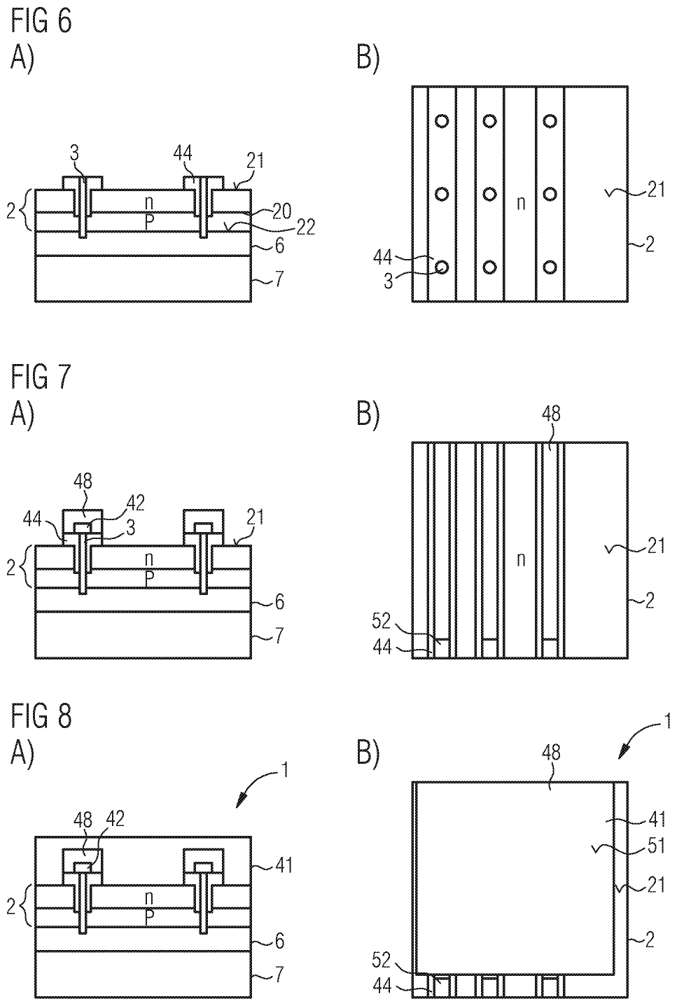

In FIGS. 3 to 9 an exemplary embodiment of a manufacturing method for semiconductor devices 1 is illustrated. According to FIG. 3, the semiconductor layer sequence 2 is grown on a growth substrate 29. Preferably, an n-type material is located on the growth substrate 29 and a p-type material is located on a side of the active zone 20 opposite to the growth substrate 29. The p-type and n-type regions are marked with an n and a p, respectively, in the figures.

In FIG. 4, it is shown that the current spreading layer 6 is deposited on the semiconductor layer sequence 2. A thickness of the current spreading layer 6 is, for example, at least 50 nm and/or at most 200 nm. Furthermore, the carrier 7 is applied to a side facing away from the growth substrate 29, for example by means of an adhesive not shown.

In the step of FIG. 5, the growth substrate 29 is removed, for example by means of etching and/or by means of a laser lift-off process. This exposes the first main side 21 of n-type material.

In the step of FIG. 6, the through-connections 3 are created. The through-connections 3 end in the current spreading layer 6. At least up to the active zone 20, seen from the first main side 21, side walls of holes for the through-connections 3 are provided with an electrically insulating material. Deviating from FIG. 6, the electrically insulating material at the sides of the through-connections 3 can also extend into the current spreading layer 6 and not end in the p-type layer.

The through-connections 3 are preferably created in a regular grid, for example in a rectangular or hexagonal grid. In addition, electrically insulating structures are preferably generated in the form of the contact mirror 44. Via the contact mirror 44, several of the through-connections 3 are connected to each other in a row.

In the step of FIG. 7, the second contact structures 42 are generated on the contact mirrors 4. Electrical isolation from the semiconductor layer sequence 2 is provided by the contact mirrors 4. Thus, an absorption of radiation generated in the semiconductor layer sequence 2 at the second contact structures 42 is prevented or greatly reduced by the contact mirrors 44.

Further, the second contact structures 42 are predominantly covered by an electrically insulating passivation layer 48. Preferably, no passivation layer is present at ends of electrically conductive strips by which the second contact structures 42 are formed. Such regions are provided for second contact pads 52 for external electrical contacting of the finished semiconductor devices 1.

According to FIG. 8, the first contact structure 41 is applied, for example by means of vapor deposition and subsequent electroplating. In this process, the second contact structures 42 and the passivation 48 are preferably covered and embedded, wherein the second contact pads 52 remain free at the edge of the strips of the second contact structures 42.

FIG. 9 shows the finished semiconductor device 1. A first contact pad 51 is formed by the first contact structure 41 for external electrical contacting. The contact pad 51 is a largest contact pad that makes up a major portion of the mounting side of the semiconductor device 1. Viewed from above, the carrier 7, in particular made of sapphire, preferably extends completely over the semiconductor device 1.

One or more metal layers can be applied for the contact pads 51, 52. In this way, the semiconductor device 1 can preferably be mounted by means of surface mounting. If comparatively thick mechanically self-supporting metallic structures are used for the contact pads 51, 52, which can be produced in particular by electroplating and comprise a thickness of around 100 μm, for example, the carrier 7 can be omitted.

The optional steps for generating the microprisms 91, 92 from FIG. 1 are not drawn in FIGS. 3 to 9 in each case to simplify the presentation. The same applies to the following figures. Regardless, the microprisms 91 and/or 92 are preferably present.

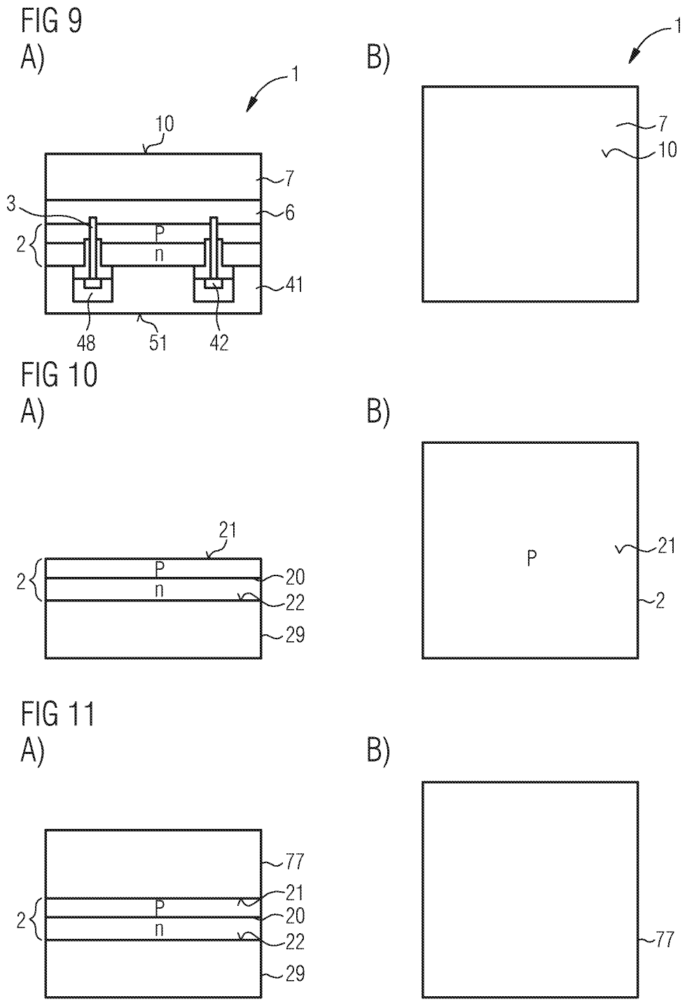

FIGS. 10 to 17 illustrate a further manufacturing method. Growing according to FIG. 10 corresponds to the method step of FIG. 3.

According to FIG. 11, a temporary intermediate carrier 77 is applied, for example made of glass, quartz glass or sapphire. Subsequently, the growth substrate 29 is removed.

According to FIG. 12, the permanent carrier 7 is then applied. The intermediate carrier 77 is removed, see FIG. 13, so that the first main side 21 is formed by p-type material of the semiconductor layer sequence 2, unlike in the method of FIGS. 3 to 9.

The method steps of FIGS. 14 to 17 are carried out analogous to the method steps of FIGS. 6 to 9. However, the through-connections 3 may terminate in the n-type layer and need not completely penetrate the semiconductor layer sequence 2. This is achieved due to the comparatively high electrical transverse conductivity of the n-type layer. The second main side 22 can thus remain a continuous, closed surface.

Optionally, in the method of FIGS. 10 to 17, the current spreading layer 6 is also created before the carrier 7 is attached. This is symbolized in FIG. 14 as a dash line. If such a current spreading layer 6 is present, the through-connections 3 preferably end at or within the current spreading layer 6, again drawn as dash lines. Alternatively, the through-connections 3 can also extend to the carrier 7 and thus completely penetrate the current spreading layer 6.

In FIGS. 15 to 17, the through-connections 3 are each drawn ending in the n-type layer and the current spreading layer 6 is not illustrated. The method steps in FIGS. 15 to 17 can nevertheless be carried out in the same way as the option in FIG. 14, i.e. with longer through-connections 3 and/or with current spreading layer 6.

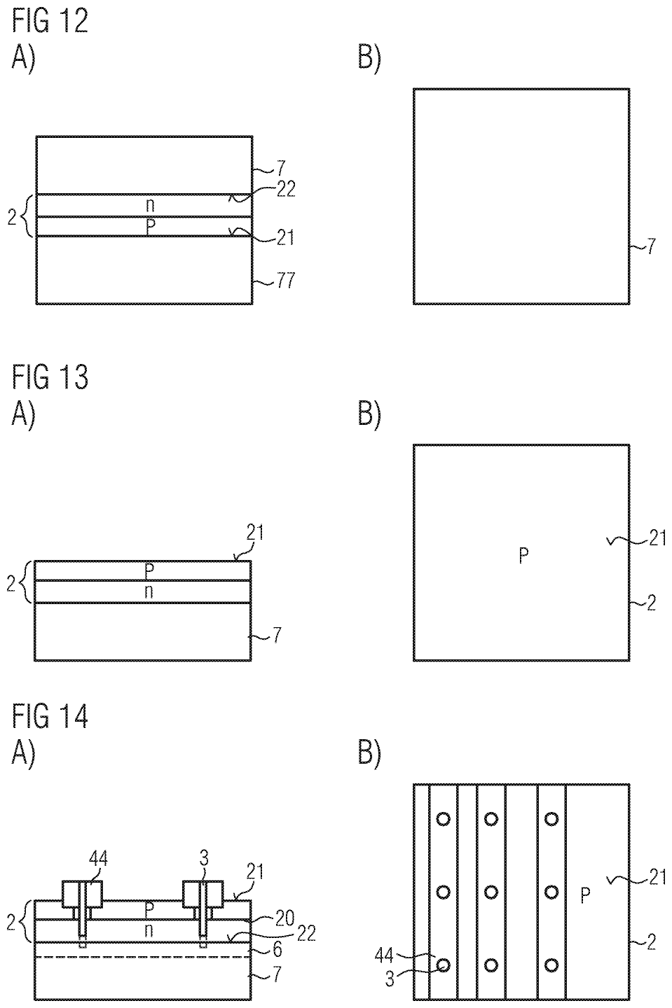

FIGS. 18 to 21 illustrate further steps of a manufacturing method. The step of FIG. 18 corresponds essentially to the step of FIG. 11, wherein the growth substrate has already been removed. Thus, the second main side 22 of n-type material is exposed.

In the step of FIG. 19, a transparent electrically conductive interconnection layer 46 is created in a star-shaped or cross-shaped manner, preferably in a structured manner. The layer 46 is for example made of a TCO such as ITO. According to FIG. 19, the layer 46 covers only a comparatively small part of the second main side 22, but can also be a continuous, full-surface layer.

In the step of FIG. 20, the current distribution structures 63 are applied in a structured manner to the regions of the layer 46. The current distribution structures 63 comprise in particular the same basic shape as the regions of the layer 46. Preferably, the regions of the layer 46 project laterally beyond the current distribution structures 63 to a small extent in each case.

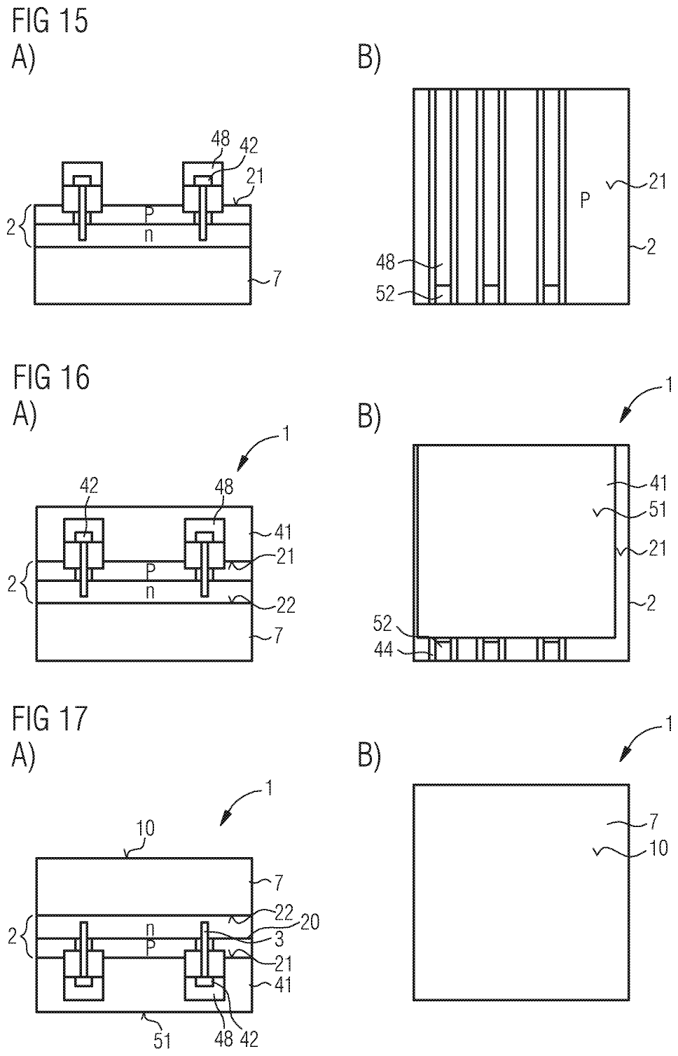

In FIG. 21 it is shown that the carrier 7 is subsequently applied. An adhesive 76 can be used for this. Thus, the regions of the layer 46 as well as the current distribution structures 63 are embedded in the adhesive 76.

The step of FIG. 21 is preferably followed by the steps of FIGS. 14 to 17. Deviating from FIG. 14, the through-connections 3 preferably end in the current distribution structures 36 or at the current distribution structures 63.

This means that the through-connections 3 can completely penetrate the regions of the layer 46 and thus also run completely through the semiconductor layer sequence 2.

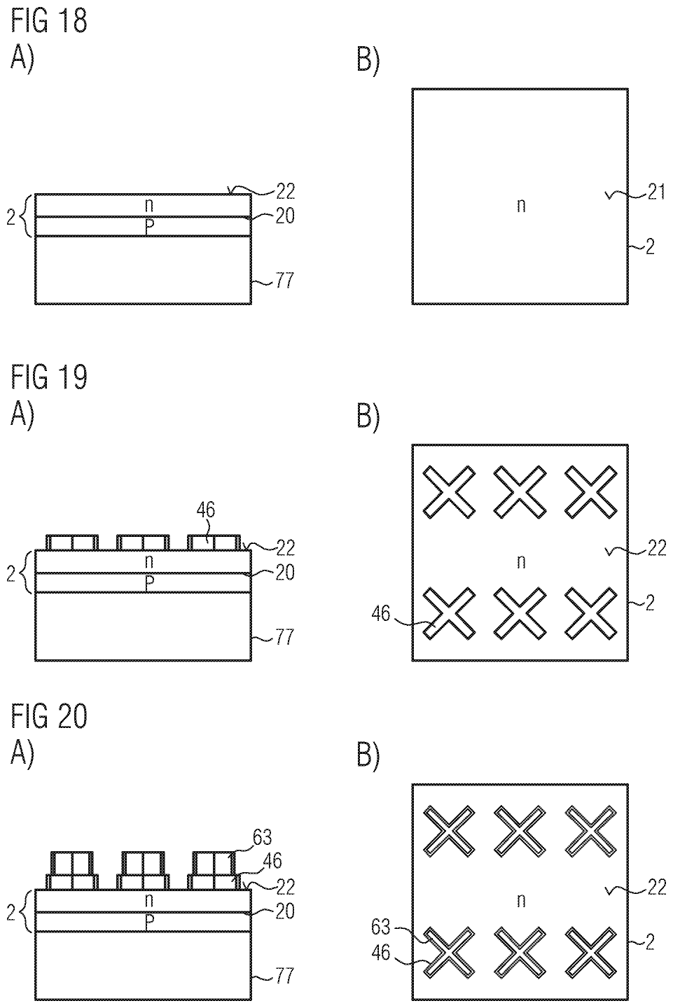

In FIG. 22 schematic top views of the first main side 21 are shown, before the passivation layer 48 and the first contact structure 41 are applied.

According to FIG. 22A, the second contact structure 42 extends in a rectangular or square grid and electrically connects groups of through-connections 3 or preferably all through-connections 3 with a low resistance. In contrast, it is shown in FIG. 22B that a hexagonal grid can also be formed by the contact structure 42.

In FIGS. 23 to 26 various possible designs of the contact pads 51, 52 are shown.

According to FIG. 23, the contact pads 51, 52 are designed as illustrated, for example, in connection with FIG. 8. That is, the second contact pads 52 are located at an edge of the first main side 21 on a single side of the first contact pad 51.

The edge around the first contact pad 51 comprises, for example, a width of at least 10 μm or 30 μm and/or of at most 100 μm or 60 μm. This may equally be the case in all other exemplary embodiments.

In contrast, in FIG. 24 the strips of the second contact structure extend beyond the first contact pad 51 on both sides. Thus, several second contact pads 52 are present on two opposite sides of the first contact pad 51 at the edge of the first main side 21.

According to FIG. 25, the second contact pads 52 are located on all four sides of the first contact pad 51. For example, the second contact structure 42 is formed as illustrated in FIG. 22A.

According to FIGS. 23 to 25, the second contact pads 52 are electrically contactable individually. This allows groups of through-connections 3 to be electrically controlled independently of one another.

Deviating from the illustrations of FIGS. 23 to 25, there can also be only one or two electrical contact pads 52 in each case, which can extend along the edge of the first main side 21 in the form of strips along one or two edges of the first contact pad 51 or also can, in accordance with a modification of FIG. 25, extend in the form of a frame around the entire first contact pad 51.

Along the strips for the second contact structures 42 of FIGS. 23 to 25, there may be different densities of through-connections in each case. Furthermore, diagonal strips for the second contact structures 42 may additionally be present, not drawn. Furthermore, it is possible to provide the strips for the second contact structures 42 with a thickness gradient, for example with thicker strips in a center of the semiconductor device 1. In this way, current densities can be adjusted without having to change a density or a shape of the through-connections 3. To achieve a coarse pixelation, each contact pad 52 may also be electrically controllable individually. The same applies to all other exemplary embodiments.

In FIG. 26, it is illustrated that the second contact pad 52 is located within the first contact pad 51. That is, seen in a plan view, the large first contact pad 51 can form a closed frame around the small second contact pad 52.

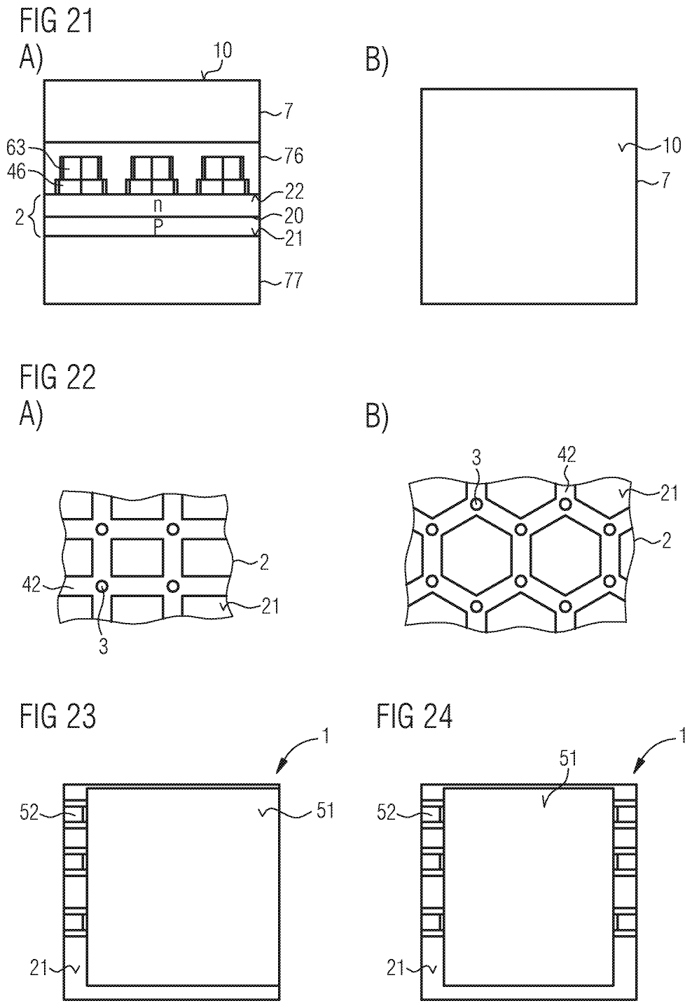

In the exemplary embodiment of FIG. 27, it is shown that the semiconductor device 1 comprises a radiation aperture 8. The radiation aperture 8 is, for example, made of a white appearing diffuse reflecting material. From an edge, the radiation aperture 8 covers a part of the emission side 10. With such an aperture 8, high luminance densities can be achieved.

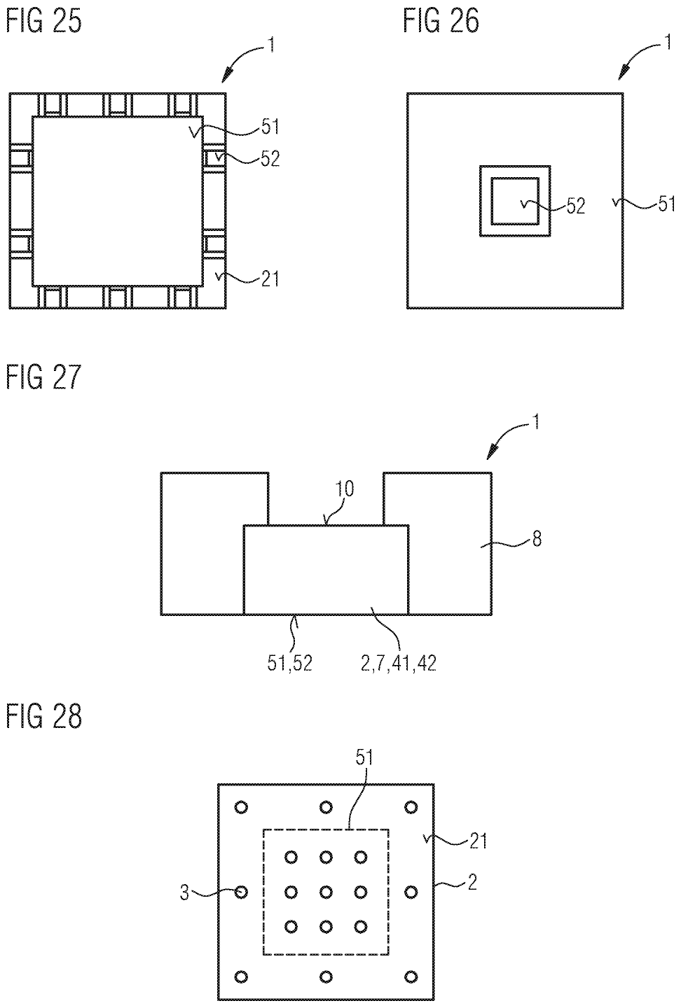

In the plan view of the first main side 21 of FIG. 28 it is illustrated that the through-connections 3 may be arranged with a density gradient. Centrally in the first main side 21, the through-connections 3 are arranged close to each other and at an edge of the first main side 21 a distance between adjacent through-connections 3 is larger.

The first contact pad 51 preferably extends completely over the region of high surface density of the through-connections 3. This is symbolized in FIG. 28 as a dash line for the first contact pad 51.

This allows higher current densities and thus increased light generation to be realized centrally in the first main side 21. Such an arrangement is in particular advantageous in combination with the radiation aperture 8 of FIG. 27 to achieve a high radiation outcoupling efficiency.

Unless otherwise indicated, the components shown in the figures preferably follow each other directly in the sequence indicated. Layers not touching in the figures are preferably spaced apart. Insofar as lines are drawn parallel to each other, the corresponding surfaces are preferably also aligned parallel to each other. Likewise, unless otherwise indicated, the relative positions of the drawn components to each other are correctly reproduced in the figures.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1. An optoelectronic semiconductor device comprising
a semiconductor layer sequence for generating red or orange light with a first main side and with a second main side,
a plurality of electrical through-connections through the semiconductor layer sequence, and
a first electrical contact structure, which electrically contacts the first main side in a planar manner, and
at least one second electrical contact structure on the first main side, wherein
the at least one second contact structure electrically connects a plurality of the through-connections to each other, and
the second contact structure is embedded in the first contact structure, such that
side surfaces of the second contact structure are predominantly covered by a material of the first contact structure, and
the second contact structure is predominantly located between the first contact structure and the semiconductor layer sequence.

2. The optoelectronic semiconductor device according to the preceding claim 1,
which is a light emitting diode, wherein
a current spreading layer of a transparent material is located on the second main side,
the through-connections terminate in or on the current spreading layer
the first contact structure comprises a first contact pad and the second contact structure comprises at least one second contact pad for external electrical contacting of the semiconductor device, and all contact pad are located on the first main side, and
the first main side and the second contact structure, as seen in a plan view of the first main side, are each covered to at least 80% by the first contact pad.

3. The optoelectronic semiconductor device according to the preceding claim 2,
in which, viewed in a plan view
the first contact pad completely and uninterruptedly covers a central region of the first main side and leaves an edge of the first main side partially or completely free, and
the at least one second contact pad is located at the edge of the first main side.

4. The optoelectronic semiconductor device according to claim 2,
in which the second contact structure comprises a plurality of strips which run parallel to one another which, as seen in a plan view of the first main side, project beyond the first contact pad on two mutually opposite sides, and
wherein each of the at least one second contact pad is attached to ends of the strips of the second contact structure.

5. The optoelectronic semiconductor device according to claim 1,
in which a plurality of second electrical contact structures are provided, so that the through-connections are electrically independently controllable of one another in groups.

6. The optoelectronic semiconductor device according to claim 1,
further comprising a carrier of a dielectric transparent material at the second main side,
wherein the carrier completely covers the second main side and forms a light outcoupling element of the semiconductor device.

7. The optoelectronic semiconductor device according to claim 1,
further comprising at least one metallic current distribution structure,
wherein the current distribution structure extends from the through-connections over a part of the second main side.

8. The optoelectronic semiconductor device according to claim 7,
in which a plurality of the current distribution structures are present which, as seen in a plan view of the second main side, each extend in a star-shaped from the associated through-connection over a part of the second main side.

9. The optoelectronic semiconductor device according to claim 7, in which exactly one current distribution structure, as seen in a plan view of the second main side, extends as a grid and electrically connects the through-connections to one another over the second main side.

10. The optoelectronic semiconductor device according to claim 2,
further comprising at least one metallic current distribution structure,
in which the at least one current distribution structure is embedded in the current spreading layer, so that the at least one current distribution structure is covered by a material of the current spreading layer on a side facing the semiconductor layer sequence as well as on a side facing away from the semiconductor layer sequence.

11. The optoelectronic semiconductor device according to claim 2,
further comprising at least one metallic current distribution structure,
in which the at least one current distributing structure is located on a side of the current spreading layer facing away from the semiconductor layer sequence, so that the current spreading layer and the current distributing structure are flush with one another in a direction away from the semiconductor layer sequence.

12. The optoelectronic semiconductor device according to claim 2,
further comprising at least one metallic current distribution structure, and
further comprising a carrier of a dielectric transparent material at the second main side, in which the at least one current distribution structure is located on a side of the current spreading layer facing away from the semiconductor layer sequence and is embedded in an adhesive,
wherein the carrier is attached to the current spreading layer with the adhesive and the current distribution structure is located between the current spreading layer and the carrier.

13. The optoelectronic semiconductor device according to claim 6, wherein the carrier is attached to the semiconductor layer sequence by means of bonding or soldering.

14. The optoelectronic semiconductor device according to claim 1,
further comprising a contact mirror at the second electrical contact structure towards the first main side,
wherein the contact mirror is reflective for orange and/or red light and is electrically insulating.

15. The optoelectronic semiconductor device according to claim 1,
wherein the through-connections exhibit a density gradient when viewed in a plan view of the second main side, such that the through-connections are arranged more densely in a center of the second main side than at an edge of the second main side.

16. The optoelectronic semiconductor device according to claim 15,
further comprising a radiation aperture partially covering the second main side from an edge,
wherein the radiation aperture is opaque and diffusely reflective.

17. The optoelectronic semiconductor device according to claim 1,
which is a light-emitting diode chip in which
the semiconductor layer sequence is based on InAlGaP,
the semiconductor layer sequence is n-doped at the first main side and the second main side is p-doped,
a transparent electrically conductive interconnection layer is located directly between the first main side and the first contact structure, and
an intended current density between the main sides is at least 10 A/cm² in operation.

18. An optoelectronic semiconductor device comprising
a semiconductor layer sequence for generating red or orange light with a first main side and with a second main side,
a plurality of electrical through-connections through the semiconductor layer sequence, and
a first electrical contact structure, which electrically contacts the first main side in a planar manner, and
at least one second electrical contact structure on the first main side,
wherein
the at least one second contact structure electrically connects a plurality of the through-connections to each other, and
the second contact structure is embedded in the first contact structure,
the first contact structure comprises a first contact pad and the second contact structure comprises at least one second contact pad for external electrical contacting of the semiconductor device, and all contact pad are located on the first main side, and
the first main side and the second contact structure, as seen in a plan view of the first main side, are each covered to at least 80% by the first contact pad,
viewed in a plan view the first contact pad completely and uninterruptedly covers a central region of the first main side and leaves an edge of the first main side partially or completely free, and
viewed in a plan view the at least one second contact pad is located at the edge of the first main side.

19. An optoelectronic semiconductor device comprising
a semiconductor layer sequence for generating red or orange light with a first main side and with a second main side,
a plurality of electrical through-connections through the semiconductor layer sequence, and
a first electrical contact structure, which electrically contacts the first main side in a planar manner,
at least one second electrical contact structure on the first main side, and
at least one metallic current distribution structure, wherein
the at least one second contact structure electrically connects a plurality of the through-connections to each other, and
the second contact structure is embedded in the first contact structure
the current distribution structure extends from the through-connections over a part of the second main side.
